(19) United States
(12) Patent Application Publication
(10) Pub. No.: US 2025/0081449 A1
(43) Pub. Date: Mar. 6, 2025

(54) ASYMMETRICAL CHANNEL FLOATING GATE THREE-STATE ONE-TIME PROGRAMMABLE NONVOLATILE MEMORY

(71) Applicant: Texas Instruments Incorporated, Dallas, TX (US)

(72) Inventors: Jack Qian, Plano, TX (US); Doug Weiser, Plano, TX (US); Tamer San, Plano, TX (US)

(21) Appl. No.: 18/240,580

(22) Filed: Aug. 31, 2023

(51) Int. Cl. H10B 20/25; G11C 17/16; G11C 17/18

(52) U.S. Cl. CPC H10B 20/25; G11C 17/165; G11C 17/18

(57) ABSTRACT

An electronic device with a non-volatile memory includes a non-volatile memory (NVM) cell selectively programmable to change a program state from a first state to a second state or to a third state, and may also include a write circuit configured to selectively program the NVM cell to change the program state from the first state to the second state by applying a programming voltage signal to a first source/drain region and to change the program state from the first state to the third state by applying the programming voltage signal to a second source/drain region. A read circuit is configured to identify the program state of the NVM memory cell as one of the first state, the second state, and the third state based on a cell voltage of the non-volatile memory cell.

### BACKGROUND

Advanced integrated circuits often include one-time programmable (OTP) non-volatile memory that can be programmed for permanent data or program code storage even if power is removed from the memory circuitry. Using three-state one-time programmable nonvolatile memory can store more data in the same silicon area which makes data protection more secure with the same silicon area to facilitate design efforts to increase circuit density and decrease device size. However, three-state one-time programmable nonvolatile memory often requires additional complex programming and read circuitry which can reduce the space savings and increase product cost.

### SUMMARY

In one aspect, an electronic device includes a non-volatile memory cell with a channel region having a first conductivity type between first and second source/drain regions having an opposite second conductivity type over a semiconductor substrate, the channel region touching the first source/drain region, and the memory cell has a gate structure over the channel region and including a gate dielectric layer over the channel region and a floating gate over the gate dielectric layer, as well as an enhanced channel region having the first conductivity type touching the second source/drain region and the channel region at a surface of the substrate.

In another aspect, a non-volatile memory includes a non-volatile memory cell with an asymmetric floating gate cell transistor selectively programmable to change a program state from a first state to a second state or a third state, and a read circuit configured to identify the program state of the non-volatile memory cell as one of the first state, the second state, and the third state based on a cell voltage of the non-volatile memory cell. The non-volatile memory cell comprises an asymmetrical channel region between a first source/drain region and a second source/drain region in a substrate under a floating gate, the asymmetrical channel region having an enhanced channel region adjacent the second source/drain region at a surface of the substrate.

In a further aspect, a method of fabricating an electronic device includes: forming a gate dielectric layer over a surface of a channel region of a semiconductor substrate, the channel region including majority charge carriers of a second conductivity type; forming a gate structure with opposite first and second sidewalls over the gate dielectric layer; implanting dopants of the second conductivity type under the first sidewall of the floating gate while blocking the dopants from the second sidewall of the floating gate; and; implanting dopants of an opposite first conductivity type into the substrate adjacent the first and second sidewalls of the gate structure, thereby forming first and second source/drain regions.

### BRIEF DESCRIPTION OF THE DRAWINGS

FIG. 1 is a partial sectional side elevation view of an electronic device having a floating gate three-state one-time programmable nonvolatile memory with an asymmetrical channel.

FIG. 1A is a schematic diagram showing the one-time programmable nonvolatile memory with a write circuit and a read circuit.

FIG. 1B is a graph of memory cell read current and cell voltage for an example floating gate three-state one-time programmable nonvolatile memory.

FIG. 1C is a graph of memory cell read current source drain voltage for an example floating gate three-state one-time programmable nonvolatile memory.

FIG. 1D is a partial top plan view of the floating gate three-state one-time programmable nonvolatile memory of FIG. 1 with an asymmetrical channel.

FIG. 1E is a simplified schematic diagram of a memory system in the electronic device of FIG. 1.

FIG. 2 is a flow diagram of a method of fabricating an electronic device.

FIGS. 3-14 are partial sectional side elevation views of the electronic device of FIG. 1 undergoing fabrication processing according to the method of FIG. 2.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. Unless otherwise stated, “about,” “approximately,” or “substantially” preceding a value means +/−10 percent of the stated value. One or more operational characteristics of various circuits, systems and/or components are hereinafter described in the context of functions which in some cases result from configuration and/or interconnection of various structures when circuitry is powered and operating. One or more structures, features, aspects, components, etc. may be referred to herein as first, second, third, etc., such as first and second terminals, first, second, and third, wells, etc., for case of description in connection with a particular drawing, where such are not to be construed as limiting with respect to the claims.

Various disclosed methods and devices of the present disclosure may be beneficially applied to memory storage in an electronic device such as an integrated circuit. While such examples may be expected to provide various improvements, such as the ability to store more than two programmed states in a memory cell, no particular result is a requirement of the present invention unless explicitly recited in a particular claim.

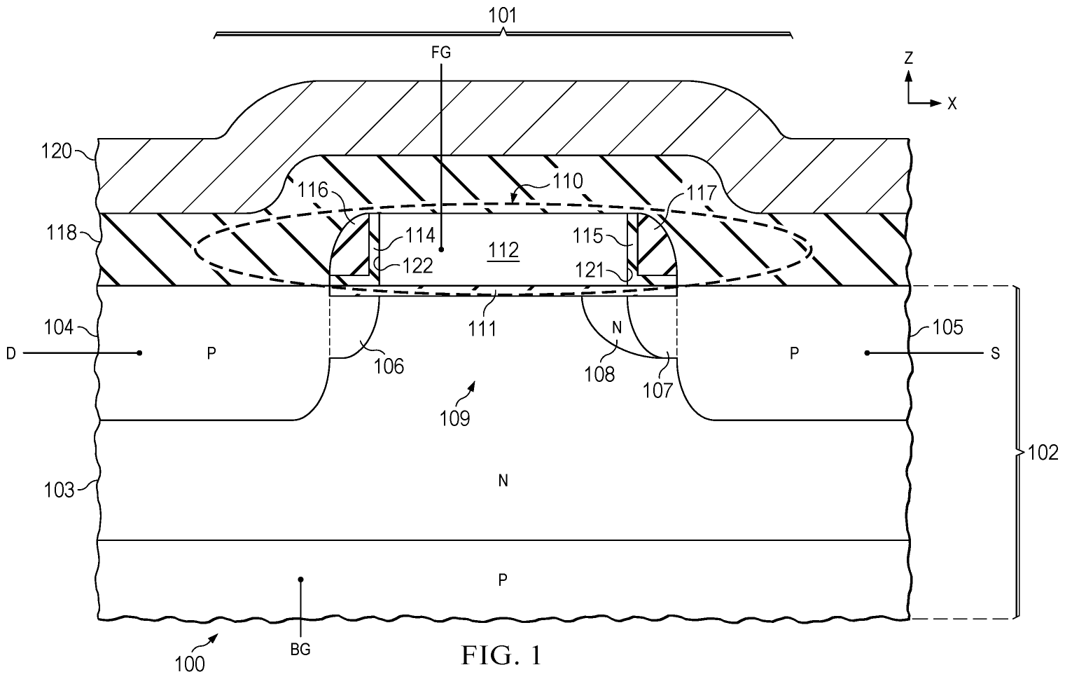

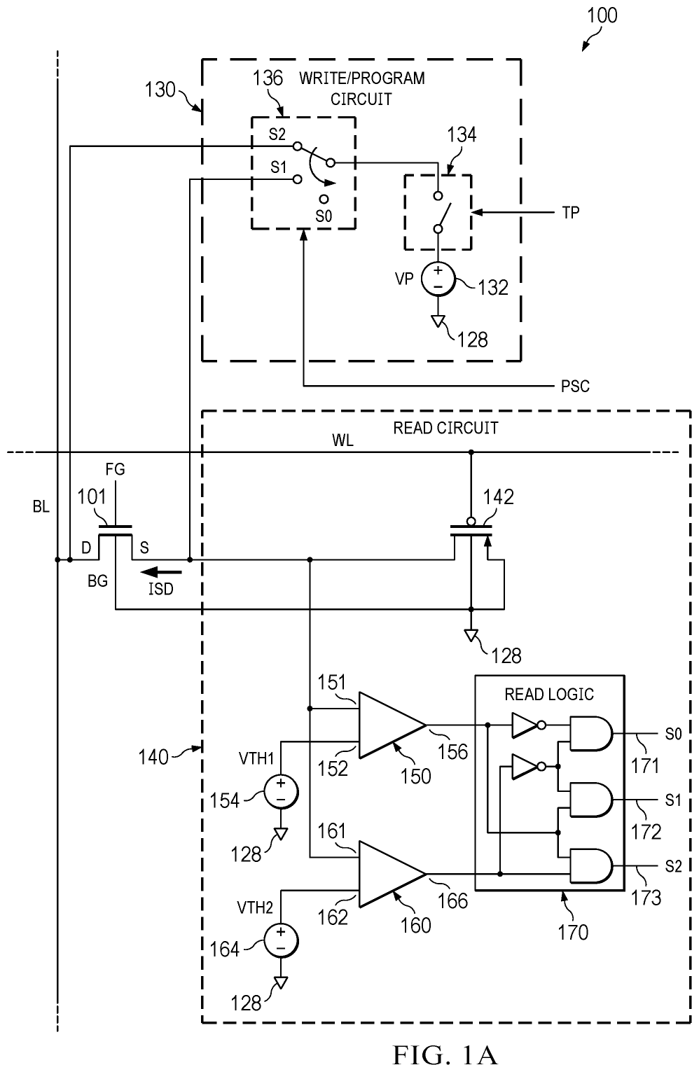

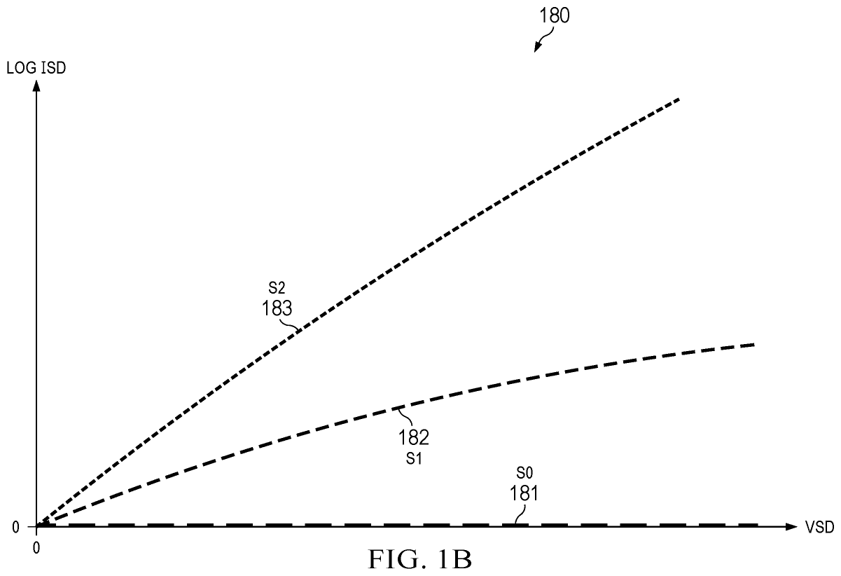

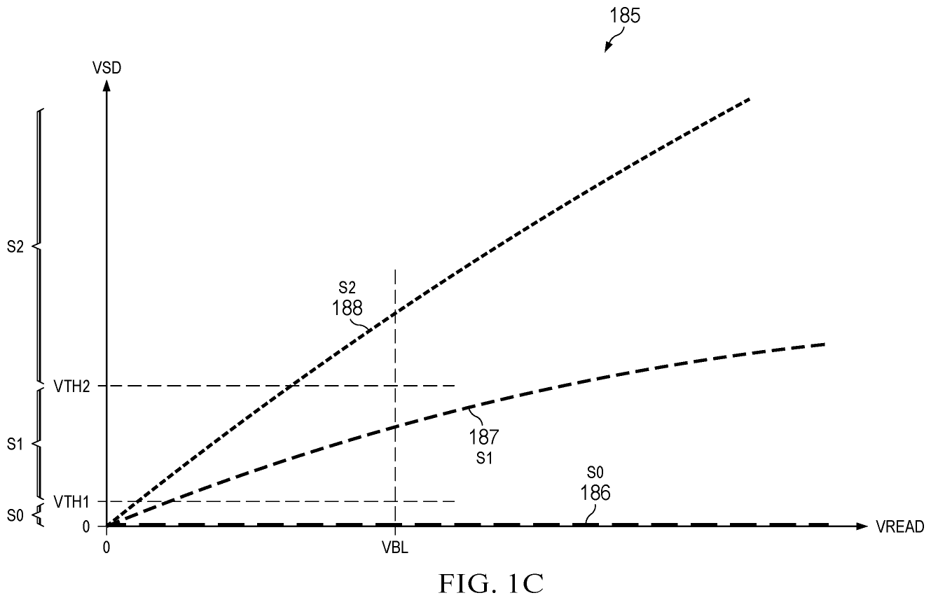

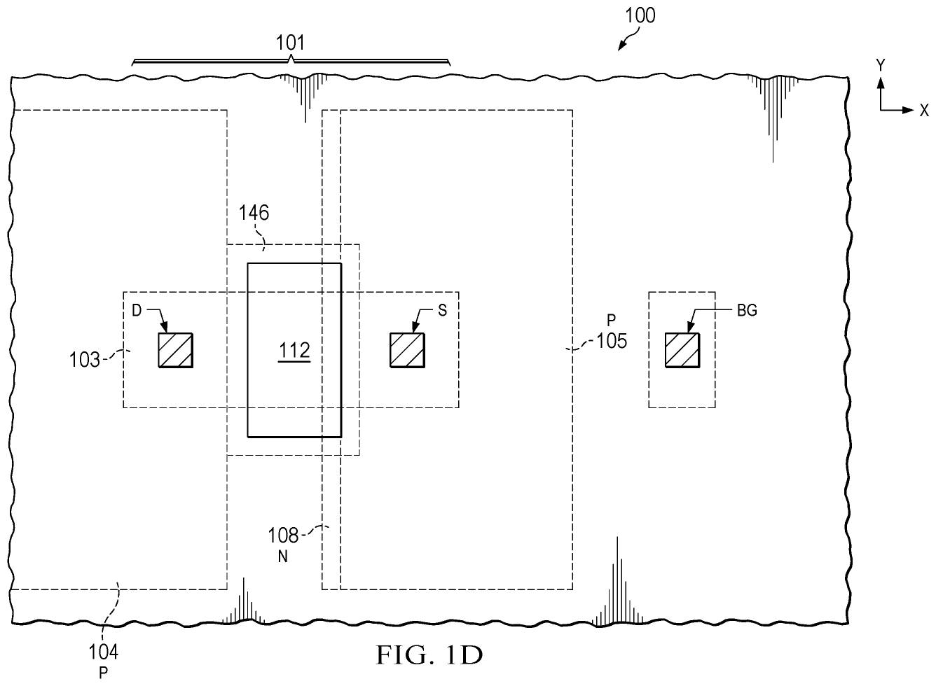

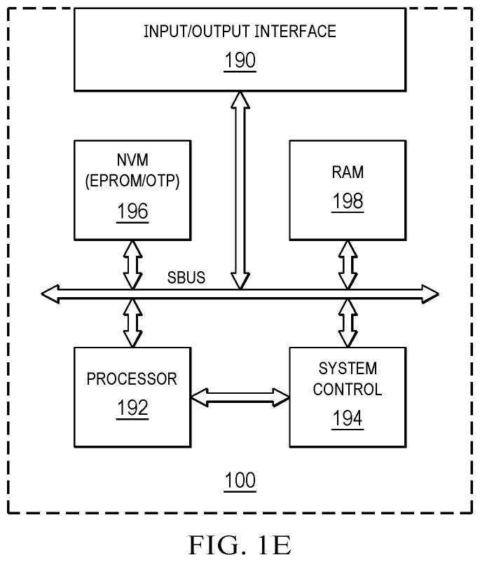

Referring initially to FIGS. 1-1F, FIG. 1 show an electronic device 100, such as an integrated circuit (IC), having a floating gate three-state one-time programmable (OTP) nonvolatile memory with an asymmetrical channel. The electronic device 100 includes one or more non-volatile memory cells 101, one of which is shown in FIGS. 1 and 1A. The asymmetric channel facilitates programming using a single programming voltage signal and the floating gate cells provide different discrete levels of accumulated charge associated with three unique program states. The OTP examples also facilitate increased circuit density and/or decreased device size by increased data density via three-state programmability while allowing use of relatively small and simple programming (e.g., write) and read circuitry, examples of which are shown in FIG. 1A.

The example memory cell 101 includes a semiconductor substrate 102, such as a silicon die, a silicon-on-insulator (SOI) structure, or other suitable semiconductor structure with majority charge carriers of a first conductivity type. The substrate 102 in one example includes an implanted well 103 having majority charge carriers of an opposite second conductivity type with a floating gate OTP memory cell transistor formed on and/or in the well 103 and/or the substrate 102. In other examples, the well 103 can be omitted. For the purpose of discussion, the well 103 is considered part of the substrate 102 such that an upper or top side or surface of the substrate 102 is coincident with a top surface of the well 103. In the illustrated example, the floating gate memory cell 101 includes a floating gate p-channel metal oxide semiconductor (e.g., PMOS) where the first conductivity type is p-type and the second conductivity type is n-type. Thus, the well 103 may be referred to as n-well 103. In another example (not shown), the first and second conductivity types can be switched.

The memory cell 101 includes a first source/drain region 104 and a second source/drain region 105. The first source/drain region 104 may be referred to herein as a drain 104 and is labeled “D” in FIGS. 1 and 1A for case of reference. The second source/drain region 105 may be referred to herein as a source 105 and is labeled “S” in FIGS. 1 and 1A for case of reference. The drain or first source/drain region 104 has a first lightly doped drain (LDD) 106 that extends from an upper portion of the first source/drain region 104 and includes majority charge carriers of the first conductivity type (e.g., boron and/or other p-type carriers). The source or second source/drain region 105 has a second LDD 107 that extends from an upper portion of the first source/drain region 104 and includes majority charge carriers of the first conductivity type (e.g., p-type). In the illustrated example, the floating gate memory cell 101 has a back gate connection to the substrate 102, labeled “BG” in FIGS. 1 and 1A, as well as a floating gate connector schematically labeled “FG” in FIGS. 1 and 1A.

The drain or first source/drain region 104 in one example includes all portions of the drain or first source/drain region 104 and the first LDD 106 in which the majority charge carriers are of the first conductivity type (e.g., p-type). The source or second source/drain region 105 in one example includes all portions of the source or second source/drain region 105 and the second LDD 107 in which the majority charge carriers are of the first conductivity type (e.g., p-type).

As further shown in FIG. 1, the memory cell 101 includes an enhanced channel region 108 adjacent the second source/drain region 105 at the upper surface of the substrate 102. The memory cell 101 also includes a channel region 109 between the first source/drain region 104 and the second source/drain region 105 in the n-well 103. As used herein, “channel region” refers to a region between the LDD 106 of the drain 104 (D) and the LDD 107 of the source 105 (S) of the OTP memory cell 101 in which a channel can be formed to provide a conductive path between the source S and the drain D, such as during programming or when the OTP memory cell 101 stores a program state, where “channel region” is not meant to convey that a channel is persistently present, but that one can be formed under appropriate operating conditions of the OTP memory cell 101.

The channel region 109 includes dopants of an opposite second conductivity type (e.g., phosphorus or other n-type donors). The enhanced channel region 108 includes majority charge carriers of the second conductivity type. In one example, the channel region 109 has a first concentration of the majority charge carriers of the second conductivity type, and the enhanced channel region 108 has a second concentration of the majority charge carriers of the second conductivity type that is greater than the first majority charge carrier concentration.

The enhanced channel region 108 is adjacent, e.g., directly in contact with and/or touching, the LDD 107 of the second source/drain region 105 at the surface of the substrate 102. In one example, the enhanced channel region 108 is formed by n-type lightly doped drain implantation in or overlapping a portion of the implanted second LDD 107 such that some or all of the enhanced channel region 108 is counter doped (includes dopants of both n and p types) and the enhanced channel region 108 has majority charge carriers of the second conductivity type. In addition, the channel region 109 is adjacent the first source/drain region 104 at the surface of the n-well 103. The position of the enhanced channel region 108 at only one end of the channel region 109 provides asymmetry to the channel of the floating gate OTP memory cell 101 and facilitates the operation with three distinct program states along with simple and compact write and read circuitry. In the illustrated example, the enhanced channel region 108 is formed by an n-type lightly doped drain (NLDD) implantation step during fabrication.

As further shown in FIG. 1, the memory cell 101 also includes a gate structure 110 that extends at least partially over the channel region 109 and provides a conductive floating gate structure labeled FG in FIGS. 1 and 1A. The gate structure 110 has a gate dielectric layer 111 (FIG. 1) over at least a portion of the channel region 109. The gate structure 110 also includes a floating gate 112 over a portion of the gate dielectric layer 111. In one example, the floating gate is or includes a conductive material, such as doped polysilicon, metal, or other electrically conductive material. The enhanced channel region 108 extends under a first end 121, or sidewall, of the floating gate 112 and the channel region 109 is adjacent the first source/drain region 104 under an opposite second end 122, or sidewall, of the floating gate 112 at the surface of the n-well 103. The memory cell 101 in one example also includes lateral sidewall structures with oxide layers 114 and 115 formed over gate dielectric layer 111 and over the respective lateral ends 122 and 121 of the floating gate 112, as well as nitride layers 116 and 117 formed over the respective oxide layers 114 and 115. The example memory cell 101 also includes a passivation layer 118 and a metal layer 120 formed over the floating gate 112.

The electronic device 100 can include further layers and structures over the illustrated portion of FIG. 1, such as a single or multilevel metallization structure (not shown). In addition, the electronic device 100 includes further transistors and other electronic components (not shown) that for the circuitry described herein, including the read and write (program) circuitry of FIG. 1A, and the metallization structure provides circuit interconnection by suitable signal and power routing.

In one implementation, the metal layer 120 is configured to operate as a control gate to modify or influence a voltage of the floating gate 112, for example, during read and/or write operations, although this is not a requirement of all possible implementations. In another example, a patterned control gate is provided above an insulation layer (not shown) on the top side of the patterned floating gate 112, although this is not a requirement of all possible implementations. In the illustrated example, the floating gate memory cell 101 operates for read and write (programming) operations with the gate structure 112 floating, although this is not a requirement of all possible implementations.

In one example, the OTP memory cell 101 of FIG. 1 is constructed as a floating gate PMOS OTP memory that includes a buried channel region 109 along with an enhanced channel region 108 formed at only one end of the buried channel region 109. The buried channel PMOS OTP memory cell 101 in this example is formed in the n-type material of the n-well 103 formed in the p-type substrate 102. The enhanced channel region 108 can be arranged such that it is located under but at approximately the same lateral positions as the corresponding first end 121 of the floating gate 112, although this is not a requirement of all possible implementations.

The enhanced channel region 108 may be formed by an n-type implant, such as an n-type lightly doped drain (NLDD) implant process, that may follow the formation of the floating gate 112. The floating gate 112 is formed over the gate dielectric layer 111. The sidewall spacer structures (layers 114-117) are formed adjacent opposite sides of the floating gate 112. The p-type lightly doped drain (PLDD) regions 106 and 107 and the p-type source/drain (PSD) regions 104 and 105 collectively form the first and second source/drains of the memory cell 101.

FIG. 1D shows a partial top view of the floating gate three-state one-time programmable nonvolatile memory cell 101 of FIG. 1 with the asymmetrical channel including conductive metal contact features (e.g., tungsten, copper, etc.) for the source S, drain D and back gate BG, the latter of which is laterally spaced along the X direction from the second source/drain 105.

FIG. 1A shows a schematic diagram of the OTP nonvolatile memory of the electronic device 100, including a ground or reference node 128 as well as a write circuit 130 and a read circuit 140 which are referenced to the reference node 128. The NLDD implant of the enhanced channel region 108 in the source of the buried channel PMOS OTP cell 101 forms a three-state OTP with an asymmetrical channel without adding extra masks during fabrication. The memory cell 101 can be programmed to two distinct on-states S1 or S2 (e.g., having different on-state source-drain currents ISD) and one off or unprogrammed state SO.

The memory cell 101 program state in one example is set by an amount of charge accumulated in the floating gate 112. In one example, the memory cell 101 has a first amount of accumulated charge in the floating gate 112 in the first (e.g., unprogrammed) state SO, for example, zero or near zero. The non-volatile memory cell 101 in this example is selectively programmable to accumulate charge in the floating gate 112 to change the program state from the first state SO to the second state S1 having a second amount of accumulated charge in the floating gate 112, the second amount of accumulated charge being greater than the first amount of accumulated charge, or to accumulate charge in the floating gate 112 to change the program state from the first state SO to the third state S2 having a third amount of accumulated charge in the floating gate 112, the third amount of accumulated charge being greater than the second amount of accumulated charge.

The write circuit 130 in FIG. 1A is configured, when the circuit of the electronic device 100 is powered and operating, to selectively set or retain a program state SO, S1, S2 of the non-volatile memory cell 101 to one of the first state SO, a second state S1, and a third state S2, where the first, second, and third states SO, S1, S2 are different from one another and detectable by the read circuit 140. In one example, the first state SO corresponds to an unprogrammed cell 101, and the write circuit 130 selectively sets the program state of the non-volatile memory cell 101 by retaining the current state, or selectively changes the program state from the first state SO to the second state S1 or to the third state S2. The non-volatile memory cell 101 is selectively programmable to change the program state from the first state SO to the second state S1 by applying a programming voltage signal VP to the second source/drain region 105, and to change the program state from the first state SO to the third state S2 by applying the programming voltage signal VP to the first source/drain region 104.

The write circuit 130 in one example includes a voltage source 132 having an output configured to provide the programming voltage signal VP, with a pulse switch 134 configured to close for a controlled programming time TP, as well as a state control switching circuit 136. In one example, the programming voltage signal VP is negative with respect to the voltage of the reference node 128. The switching circuit 136 is configured according to a program state control signal PSC to prevent connection of the output of the voltage source 132 to the non-volatile memory cell 101 to retain the program state of the non-volatile memory cell 101 in the first state SO (the switching circuit 136 connecting the output of the pulse switch 134 to the SO connection in FIG. 1A). The switching circuit 136 in this example is also configured according to the program state control signal PSC to selectively connect the output of the voltage source 132 to the second source/drain region 105 to set the program state of the non-volatile memory cell 101 to the second state S1 (the switching circuit 136 connecting the output of the pulse switch 134 to the S1 connection in FIG. 1A), and to selectively connect the output of the voltage source 132 to the first source/drain region 104 to set the program state S0, S1, S2 of the non-volatile memory cell 101 to the third state S2 (the switching circuit 136 connecting the output of the pulse switch 134 to the S2 connection in FIG. 1A). The asymmetry of the channel of the memory cell 101 allows the use of a single voltage source 132 with a single amplitude of the programming voltage signal VP to program the memory cell 1012 either the second state S1 or the third state S2, and provides a compact solution compared with providing different programming voltages or signals for a three-state of TP memory.

In one example, the pulse switch 134 and the switching circuit 136 are implemented using transistors of the electronic device 100 to implement an on-board write/program circuit 130. In one implementation, a host circuit, such as a programming controller of the electronic device 100 or of a programming system implemented during manufacture or set up of the electronic device 100 generates the controlled programming time signal TP of a fixed duration to selectively connect the output of the voltage source 132 to the input of the switching circuit 136. The controlling system sets the program state control signal PSC to connect the input of the switching circuit 136 to the appropriate connection S0, S1 or S2 to implement the desired program state of the memory cell 101.

The OTP memory cell 101 can be programmed (sometimes referred to as “burning”) to store a particular logic or program state. When a programming voltage of sufficiently high magnitude is driven across the source and drain of the memory cell 101, the programming voltage may cause charge from within the channel of the OTP memory cell 101 to transfer to the floating gate (112 in FIG. 1). The asymmetry of the channel in the memory cell 101 by virtue of the enhanced channel region 108 at only one end of the channel (e.g., adjacent the LDD 107 of the second source/drain region 105 in FIG. 1) results in a different amount of charge transfer and accumulation in the floating gate 112 based on whether the switching circuit 136 applies the programming voltage signal VP to the first or second source/drain of the memory cell 101.

The example one-time programmable memory cell 101 is shown in FIG. 1A in a memory array which may include multiple rows and columns of such cells 101. Word lines of the array allow corresponding rows of memory cells to be individually selected for read or write operations, and the example memory cell 101 is selectively connected to the reference node 128 by a cell access or select transistor 142 (e.g., PMOS) based on a select signal at the corresponding word line labeled WL. Bit lines of the array allow selection of corresponding columns of memory cells 101, and the illustrated memory cell 101 is connected to one such bit line labeled BL.

The program state stored by the OTP memory cell 101 can be read by accessing the OTP memory cell 101 through activation of the select transistor 142 by asserting an appropriate signal on the word line WL (e.g., a logic low signal in the case of a PMOS select transistor 142 as shown in FIG. 1A). While the select transistor 142 is depicted as a PMOS transistor in FIG. 1A, an NMOS access transistor could also be used in other examples depending on whether the word line is driven with a logic low or logic high signal to select the OTP memory cell 101. The select transistor 142 operates as an access transistor with its gate terminal connected to the word line WL. The memory cell 101 operates as an OTP memory with the floating gate FG left unconnected to provide non-volatile data storage.

The example read circuit 140 in FIG. 1A is configured to identify the unique program state S0, S1 or S2 of the non-volatile memory cell 101 as one of the first state S0, the second state S1, and the third state S2 based on a cell voltage of the non-volatile memory cell 101. The drain D of the memory cell 101 (e.g., the first source/drain region 104 and LDD 106 in FIG. 1 above) is connected to the bit line BL and also to the S2 output connection of the write circuit 130. The source S of the memory cell 101 (e.g., the second source/drain 105 and LDD 107 in FIG. 1) is connected to a drain of the cell select transistor 142 and is also connected to the S1 output connection of the write circuit 130. A source of the cell select transistor 142 is connected to the reference node 128. In the illustrated implementation, the back gate BG of the floating gate memory cell 101 is connected to the reference node 128, and a back gate of the cell select transistor 142 is connected to the reference node 128.

In a read operation, the read circuit 140 in FIG. 1A senses a cell voltage of the selected memory cell 101 to determine the program state. In the illustrated example, the read circuit 140 senses the cell voltage at the source S of the floating gate memory cell 101 (e.g., the voltage of the second source/drain 105 and LDD 107 in FIG. 1). The read circuit 140 includes a comparator circuit that is configured to compare the cell voltage to first and second threshold voltages VTH1 and VTH2. The absolute value of the second threshold voltage VTH2 in this example is greater than the absolute value of the first threshold voltage VTH1.

The comparator circuit in the example of FIG. 1 includes a first comparator 150 with a first input 151 connected to the source S of the memory cell 101 to sense the cell voltage, as well as a second input 152 connected to the output of a first threshold or reference voltage source 154 with the first threshold voltage VTH1. The first comparator 150 has a first comparator output 156. The comparator circuit in this example also includes a second comparator 160 with a first input 161 connected to the source S of the memory cell 101 to sense the cell voltage, as well as a second input 162 connected to the output of a second threshold or reference voltage source 164 with the second threshold voltage VTH2. The second comparator 160 has a second comparator output 166.

The read circuit 140 in FIG. 1A also includes a read logic circuit 170 that is configured to identify the program state S0, S1 or S2. The logic circuit 170 in one example includes inverters and logic gates (e.g., AND Gates), with a first AND gate that provides a first logic output 171 with an active state indicating the identified program state as the first state S0 responsive to the cell voltage being less than both the respective first and second threshold voltages VTH1 and VTH2. The logic circuit 170 in this example also includes a second AND gate that provides a second logic output 172 with an active state indicating the identified program state as the second state S1 responsive to the cell voltage being greater than or equal to the first threshold voltage VTH1 and less than the second threshold voltage VTH2. A third AND gate 173 in the logic circuit 170 has an active state indicating the identified program state as the third state S2 responsive to the cell voltage being greater than the first threshold voltage VTH1 and greater than or equal to the second threshold voltage VTH2.

FIG. 1B shows a graph 180 with curves 181 (S0), 182 (S1), and 183 (S2) illustrating example memory cell read current (LOG ISD) and cell voltage (VSD) for an example instance of the floating gate three-state one-time programmable nonvolatile memory cell 101. FIG. 1C shows a graph 185 with curves 186 (S0), 187 (S1), and 188 (S2) that illustrate memory cell source drain voltage (VSD) for an example floating gate three-state one-time programmable nonvolatile memory as a function of applied read voltage VREAD based on the bit line voltage signal during a read operation. In one limitation, the bit line voltage (FIG. 1A) is brought to a negative voltage relative to the voltage of the reference node 128 during a read operation, causing source drain current ISD to flow from the reference node 128 through the select transistor 142 to the source S of the memory cell 101, and through the channel of the memory cell 101 to the drain D of the memory cell 101 and the bit line BL.

The graph 185 in FIG. 1C shows a vertical dashed line representing one example bit line voltage labeled VBL, as well as lateral or horizontal dashed lines representing example implementations of the first threshold voltage VTH1 and the second threshold voltage VTH2. As a result of the different amounts of accumulated charge for the different program states S0, S1, and S2 in the floating gate 112 during programming, the sensed cell voltage (e.g., at the source S) of the memory cell 101 provides distinct cell voltage levels or ranges that can be accurately detected by appropriate setting of the threshold voltages VTH1 and VTH2. In one example, the current-voltage curves 182 and 183 in FIG. 1B result from programming using the same VP/TP program/write parameters selectively applied to the source S or the drain D, where the second program state S1 in one example has an on-state current Ion1 of approximately 38 μA, at a drain voltage of approximately 1 V, and the third program state S2 has an on-state current Iₒₙ₂ of approximately 82 μA, at a drain voltage of approximately 1 V, and the on-state current difference at the different on-states S1 and S2 is great enough to distinguish the two states using the read circuit 140.

FIG. 1E shows a simplified schematic diagram of a memory system that can be included in certain implementations of the electronic device 100. The electronic device 100 in this example includes an input/output (I/O) interface 190, a processor 192, the system control, 194, a nonvolatile memory (NVM) 196 (e.g., EPROM/OTP), and a random-access memory 198 (e.g., RAM) which are connected to a system bus SBUS. Various memory resources, including the RAM 198 and the NVM 196 reside on the system bus SBUS and are thus accessible to the processor 192.

The NVM 196 can be used generally for persistent storage of data, whereas the RAM 198 typically loses its data state once power is removed from the device 100. The non-volatile memory may include electrically programmable read-only-memory (EPROM) that can be erased, such as by exposure to ultraviolet light or electrically by application of a particular electrical bias (EEPROM), one-time-programmable (OTP) memory that cannot be erased once written, or a combination of such memories. The NVM 196 may serve as program memory storing program instructions executable by the processor 192, while RAM 198 serves as data memory. In some cases, program instructions may reside in RAM 198 for recall and execution by processor 192. Other system functions are implemented in the electronic device 100 by the system control logic 194 and the input/output interface 190.

The processor 192 in one example controls the general operation of the electronic device 100. For instance, the processor 192 can provide the processing capability to execute an operating system, programs, user and application interfaces, and any other functions of the device 100. The processor 192 can include a general-purpose or application-specific (ASIC) processor, field-programmable gate array (FPGA), graphics processor (GPU), digital signal processor, a system-on-chip (SoC), microcontroller, and/or related chip sets. The electronic device 100 of FIG. 1E can be any type of device that incorporates memory and/or non-volatile memory. For example, the device 100 can be a microcontroller unit or embedded processing unit. In one such implementation, the electronic device 100 can be a microcontroller unit (MCU) capable of operating over a wide temperature range with generally low power consumption, and which includes a low power processor, a volatile memory, such as SRAM, non-volatile memory, as well as analog and mixed signal and power management circuitries. Such a device can be suitable for a number of applications in various industries, for example, industrial and automotive applications. In other examples, the electronic device 100 can be a computing device, such as a mobile telephone (including smartphones), digital media player, a desktop, tablet, or notebook computer, a wearable computing device, and so forth. In such examples, the device 100 can include additional functional blocks not shown in FIG. 1E, such as input structures, RF circuitry to communicate with a network and/or with other electronic devices, a power source, and/or a display. The various functions of the device 100 can be realized and implemented using hardware elements (e.g., circuitry), software elements (e.g., computer instructions stored on a tangible computer-readable medium) or a combination of both hardware and software elements.

The example three-state OTP nonvolatile memory and the cells 101 thereof with an asymmetrical channel can store more data in the same silicon area compared with binary (two state) cell structures. The use of the three-state memory cell 101 makes the data protection more secure with the same silicon area and facilitates reduced device size and cost and/or increased circuit density. In many fabrication process flows that already have NLDD implant steps, the asymmetrical channel floating gate OTP memory cell 101 can be produced without any additional masks or added manufacturing cost. The illustrated example provides an NLDD implant to form the enhanced channel region 108 adjacent to (e.g., partially in) the source S of the floating gate buried channel PMOS OTP cell 101 to create a three-state OTP without added masks, which can be programmed to two distinct on-states (S1 or S2) with different Ion values and one off state (S0), where the program and read conditions are the same on different terminals and a single programming voltage source 132 can be used for programming.

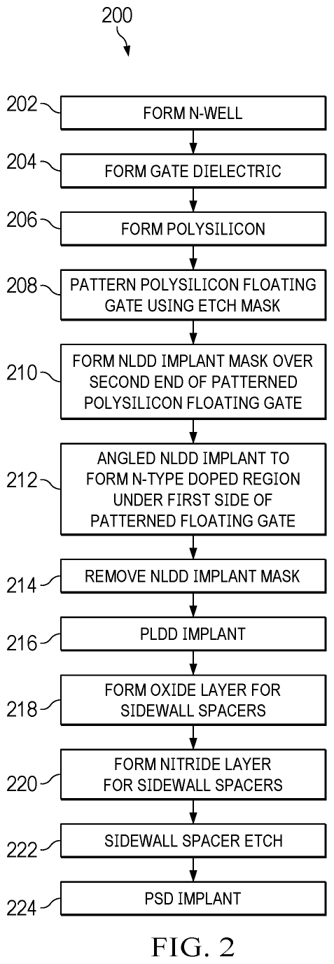

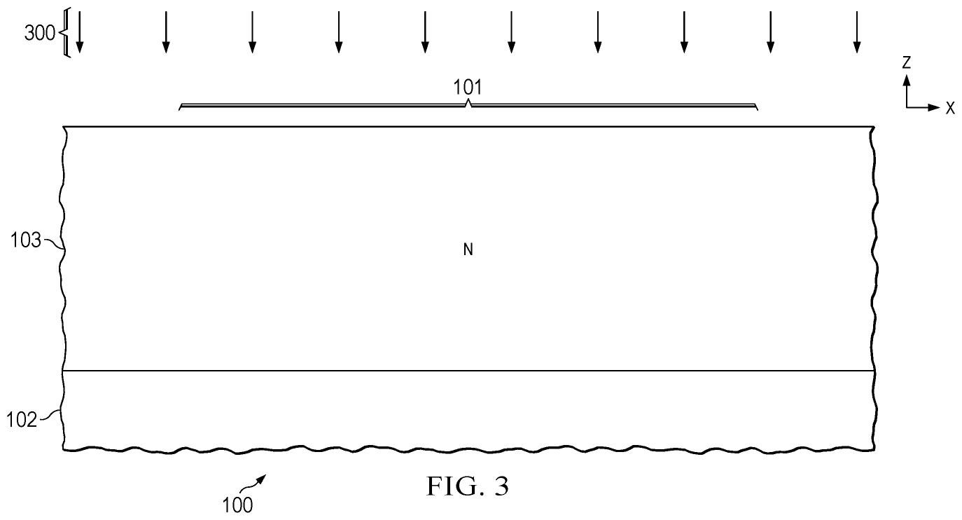

Referring also to FIGS. 2-14, FIG. 2 shows a method 200 of fabricating an electronic device, and FIGS. 3-14 show the example electronic device 100 undergoing fabrication processing according to the method 200. In the illustrated example, the method 200 includes forming the n-well in a starting wafer at 202. FIG. 3 shows a prospective OTP memory cell portion labeled 101 in one example, in which an implantation process 300 is performed that deposits phosphorus or other n-type dopants to form the n-well 103 including a prospective channel region (e.g., 109 in FIG. 1 above) in an upper portion of the p-type starting semiconductor (e.g., silicon) substrate 102. While not limited to any particular value, the n-well 103 may doped with phosphorous to a concentration of 1-5E17 atoms·cm⁻³, or in some examples about 2.7E17 atoms·cm⁻³. The substrate 102 may be formed from any suitable material as known to those skilled in the art, such as gallium arsenide, gallium nitride, germanium, silicon-germanium, silicon carbide, indium phosphide, epitaxial formations, or other semiconductor substrate materials. Other types of n-type dopants may include arsenic or antimony. During the formation of the n-well 103 in the p-type substrate 102 in one example, a patterned photoresist layer (not shown) is formed over the substrate 102, with a thickness corresponding to the wavelength of radiation used to pattern the photoresist. The photoresist layer may be formed over the substrate 102 using any suitable technique, such as spin coating or spin casting deposition. Once deposited, the photoresist layer can be etched, such as by wet etching or reactive ion etching (RIE), to provide a patterned photoresist layer that serves as a mask to define the area of the n-well 103 during implant of the n-type dopants. The mask provided by the photoresist layer can be sized such that it is greater than the area of a floating gate formed over the n-well 103 during subsequent processing. In one example, the n-well 103 formed in the substrate 102 has a thickness or depth of approximately 1.5 μm to approximately 2 μm.

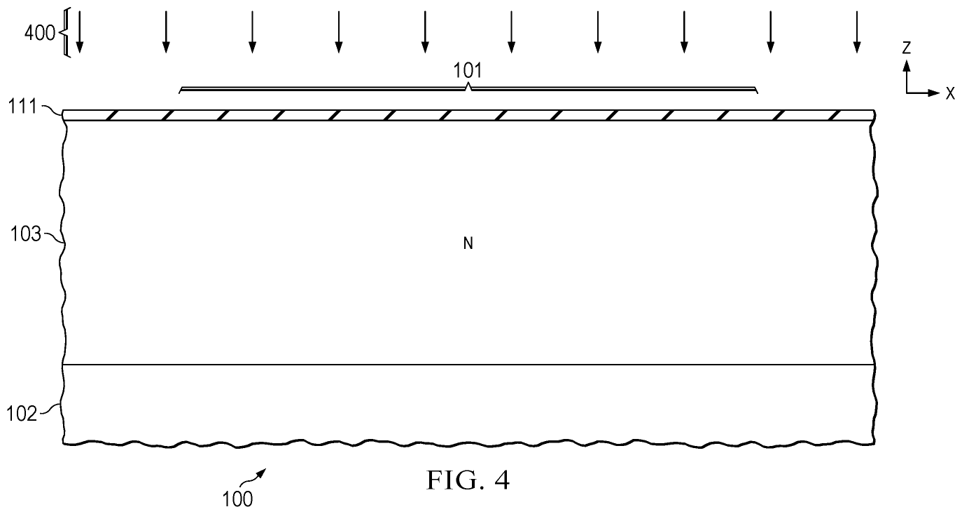

The method 200 continues at 204 in FIG. 2 with gate dielectric (e.g., gate oxide) formation. FIG. 4 shows one example, in which a process 400 is performed that forms the gate dielectric layer 111 over a surface of a prospective channel region of the substrate 102 (n-well 103). In one example, the gate dielectric layer 111 is or includes silicon dioxide in the deposition process 400 includes thermal oxidation of the silicon of the prospective channel to form the gate dielectric layer 111. The gate dielectric layer 111 can be formed using an oxidation process 400, such as wet and/or dry thermal oxidation processing. Other processes 400 can be used to form the gate dielectric layer 111, such as a chemical vapor deposition (CVD) technique (including low pressure CVD (LPCVD), plasma enhanced CVD (PECVD), and rapid thermal CVD (RTCVD)) or physical vapor deposition (PVD). The gate dielectric layer 111 in one example can have a thickness of between approximately 10 nm and 20 nm in one example, e.g., approximately 13 nm. Further, the gate dielectric layer 111 can be formed using any suitable oxide material, such as silicon dioxide (SiO₂), aluminum oxide (Al₂O₃), zirconium oxide (ZrO₂), or lanthanum oxide (La₂O₃), etc.

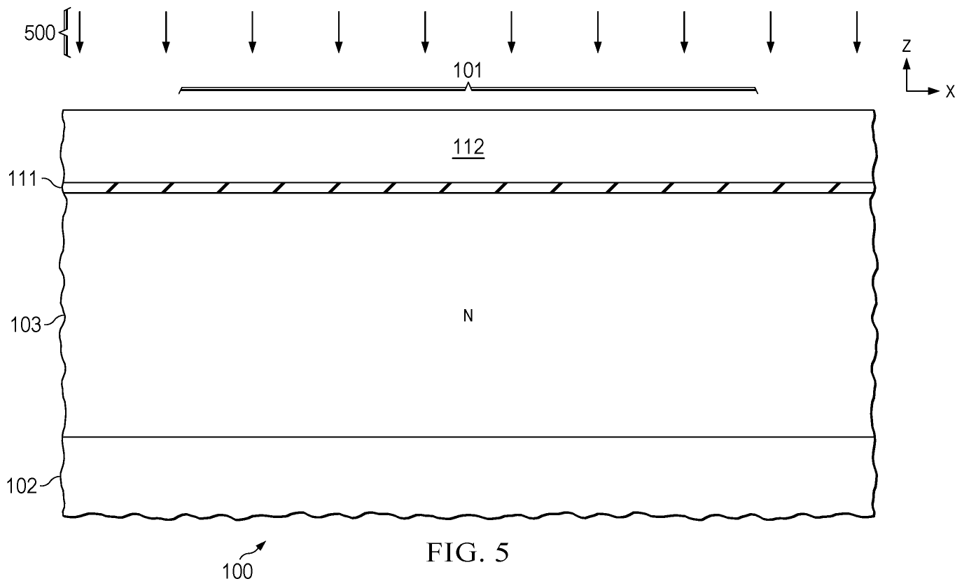

The method 200 continues at 206 and 208 in FIG. 2 with polysilicon or other conductive layer formation and floating gate patterning to form the gate having first and second ends over the gate dielectric layer 111. FIG. 5 shows one example of the polysilicon formation at 206, in which a deposition process 500 is performed that forms a layer 112 of polysilicon over the gate dielectric layer 111. The layer 112 in one example can be polysilicon and can be formed using any suitable technique, such as CVD, LPCVD, or PECVD. If polysilicon material is used to form the gate layer 112, the polysilicon can be formed in a polycrystalline state or an amorphous state that is later converted to a crystalline state. The polysilicon can also be formed using in-situ doping techniques and implantation techniques. In one example, the polysilicon layer of the gate structure 112 can have a thickness of between approximately 300 nm to 400 nm, for example, approximately 360 nm.

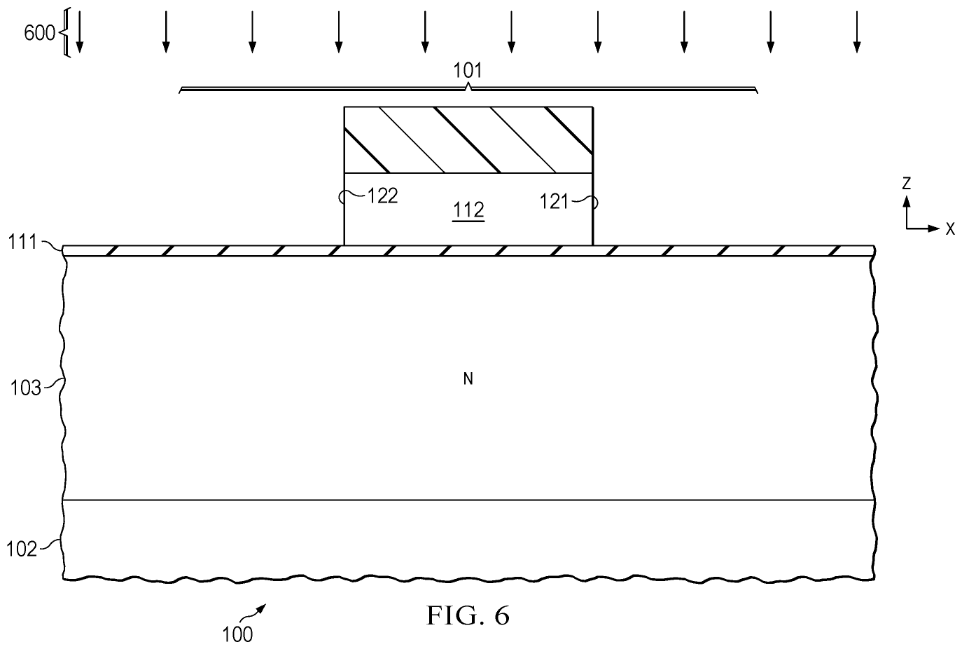

At 206, the deposited polysilicon is patterned to form a patterned floating gate structure 112. FIG. 6 shows one example, in which an etch process 600 is performed using a photoresist or other suitable mask that covers the prospective gate structure 112 and exposes the deposited polysilicon above the prospective source/drain regions. In other implementations, one or more layers of conductive material, such as heavily doped polysilicon, metals, etc. are formed and patterned at 206 and 208 in FIG. 2. The etch process 600 in the example of FIG. 6 provides a patterned gate structure 112 with the respective first and second lateral ends 121 and 122 as described above and exposes the gate dielectric layer 111 on either side of the patterned gate 112. Separate or subsequent implantation processes can be used in certain implementations to dope the gate structure 112, for example, to increase a conductivity thereof alone or in combination with in-situ doping during deposition of the polysilicon layer of the gate structure 112. In one example, the patterned polysilicon gate 112 as a length of between approximately 0.4 μm to 1 μm, for example, approximately 0.7 μm. The etch process 600 in one example can include any suitable wet or dry etching processing, such as chemical wet etching, plasma etching, etc. After the etching and formation of the floating gate 112, the photoresist layer or mask can be stripped off the floating gate and the structure cleaned using any suitable technique, such as ultraviolet exposure, sulfuric acid (H₂SO₄), or plasma etching for removal of the photoresist layer followed by SPM or RCA cleaning.

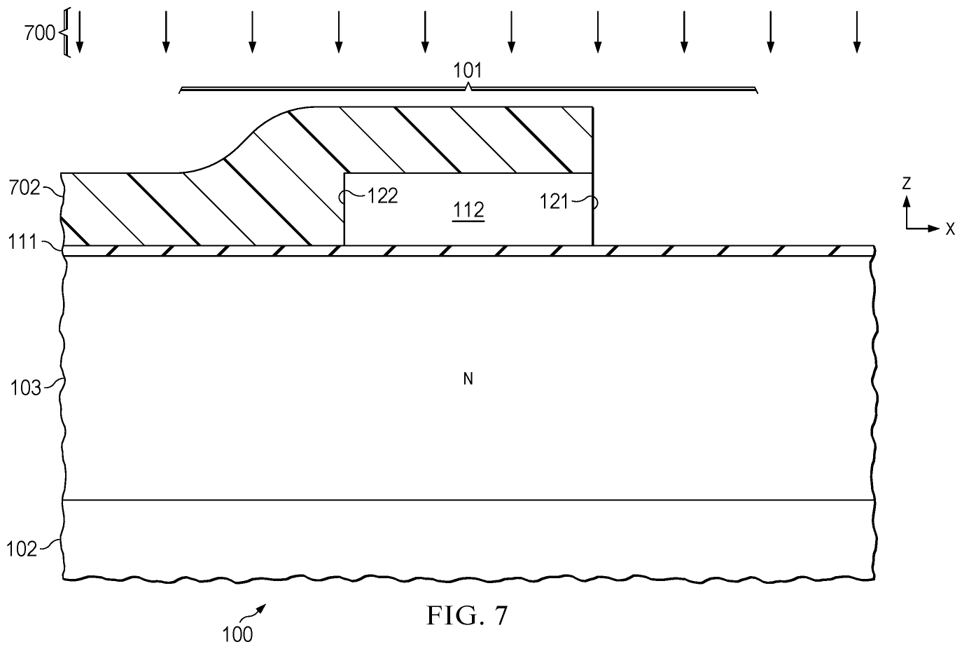

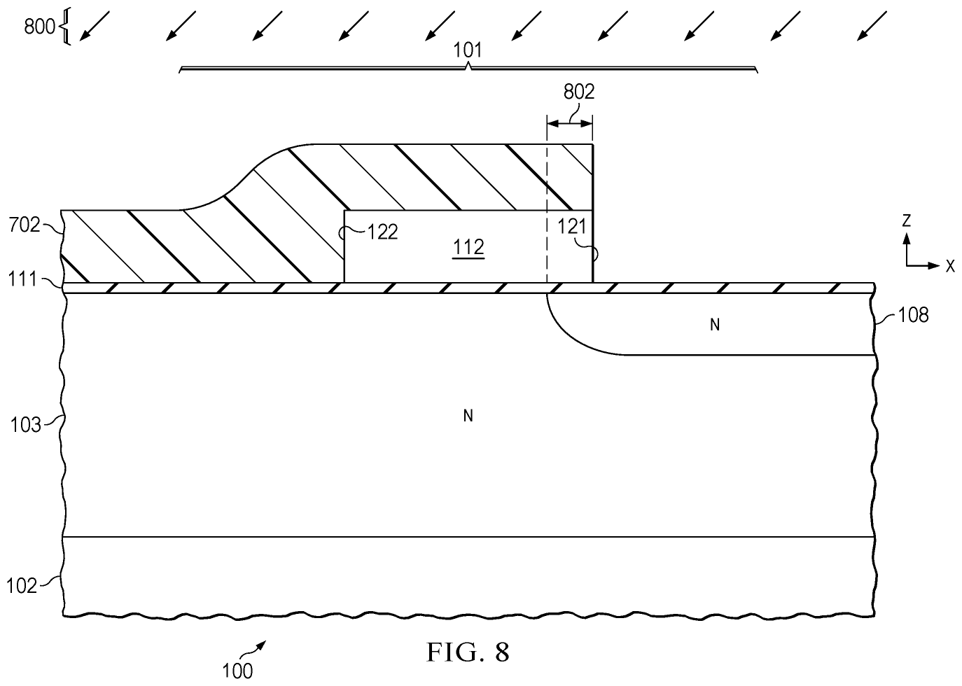

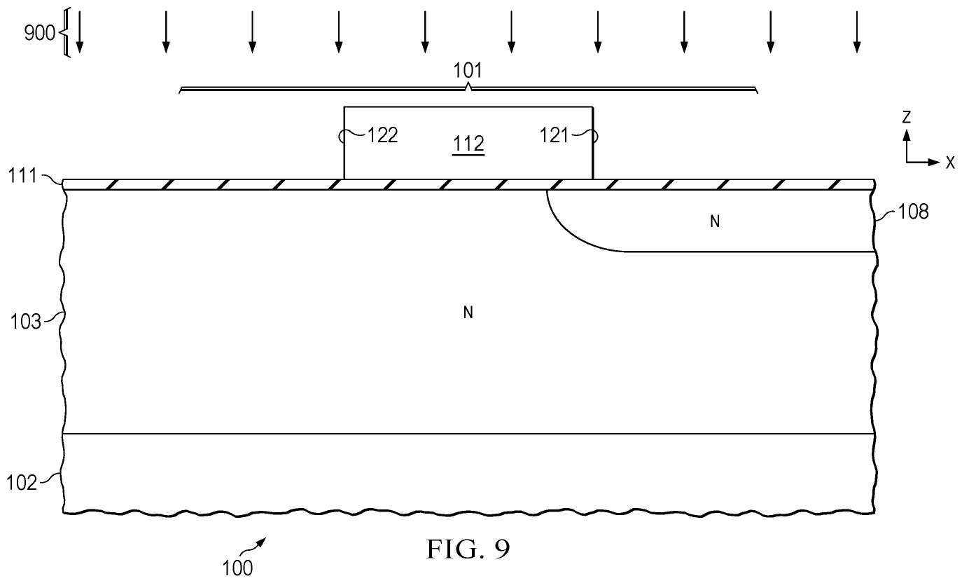

The method 200 continues at 210 in FIG. 2 with n-type lightly doped drain implantation. FIGS. 7 and 8 show one implementation of NLDD processing to implant the enhanced channel region 108 with phosphorus or other n-type dopants to form the enhanced channel region 108 at least partially under the first end 121 of the patterned floating gate 112. At 210 in FIG. 2, the method 200 includes forming an implant mask that covers the second end 122 of the patterned polysilicon floating gate 112. FIG. 7 shows one example, including deposition and patterning of an implant mask 702 that covers the patterned floating gate 112 along with the gate dielectric layer 111 to the left in the orientation shown in the figure, and the mask 702 exposes the first end 121 of the floating gate 112 and the gate dielectric layer 111 to the right of the gate 112. At 212 in FIG. 2, the method 200 continues with NLDD implantation to form the enhanced channel region 108. FIG. 8 shows one example, in which an implantation process 800 is performed using the implant mask 702. The implantation process 800 implants the enhanced channel region 108 with phosphorus or other n-type dopants or charge carriers at the surface of the n-well 103 and at least partially under the first end 121 of the floating gate 112. In one example, the implantation process 800 is an angled lightly doped drain implantation process 800 using an ion implanter that implants dopants at a non-zero angle to a plane of the top surface of the substrate 102, for example at a non-zero angle of less than 90 degrees with respect to the surface of the n-well 103, for example, approximately 45 degrees in one implementation. This facilitates provision of n-type dopants under the first end 121 of the patterned gate 112 to enhance the asymmetry of the resulting memory cell channel. While not limited to any particular value, the n-well 103 may doped with phosphorous to a concentration of that is about the same as the dopant concentration of the n-well 103. In the example in which the n-well 103 is doped to approximately 2.7E17 atoms·cm⁻³, the implantation process may implant phosphorous with a flux of approximately 2.3E13 atoms·cm⁻² at an energy of about 95 keV. The method 200 continues at 214 in FIG. 2 with removal of the implant mask 702, for example, by a mask removal process 900 shown in FIG. 9.

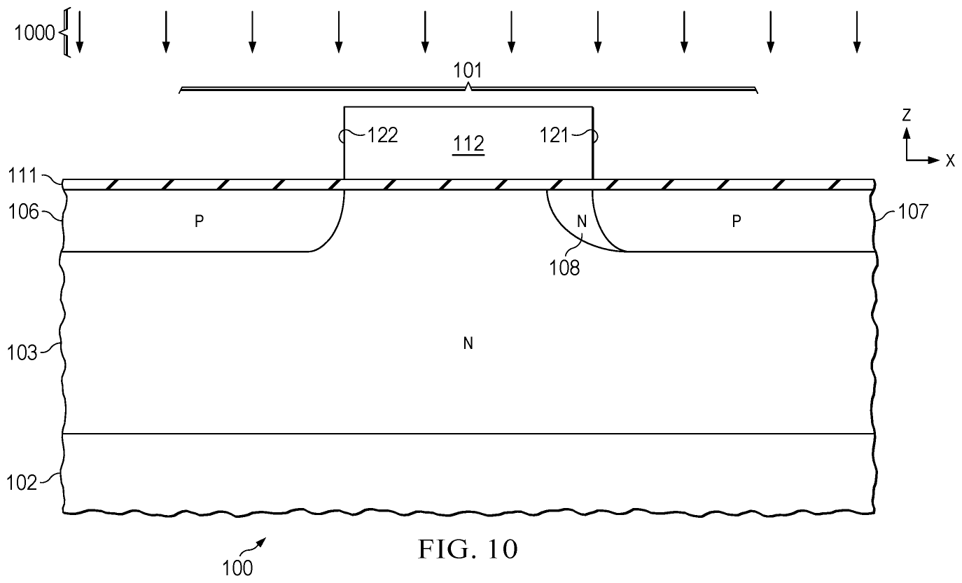

The method 200 continues with p-type lightly doped drain implantation at 216 in FIG. 2. FIG. 10 shows one example, in which an implantation process 1000 is performed that implants boron or other p-type dopants to form the LDD regions 106 and 107. The implantation process 1000 in one example is a self-aligned process using the patterned gate 112 as an implant mask. In the illustrated example, the p-type implant may slightly counter dope a portion of the enhanced channel region 108 under the first end 121 of the patterned gate 112, but the illustrated portion of the enhanced channel region 108 includes a higher concentration of n-type carriers then p-type carriers, and thus has a majority carrier concentration of the second (e.g., n-type) charge carriers. The implant process 1000 may be conventional, e.g., as performed for an analogous transistor lacking the enhanced channel region 108.

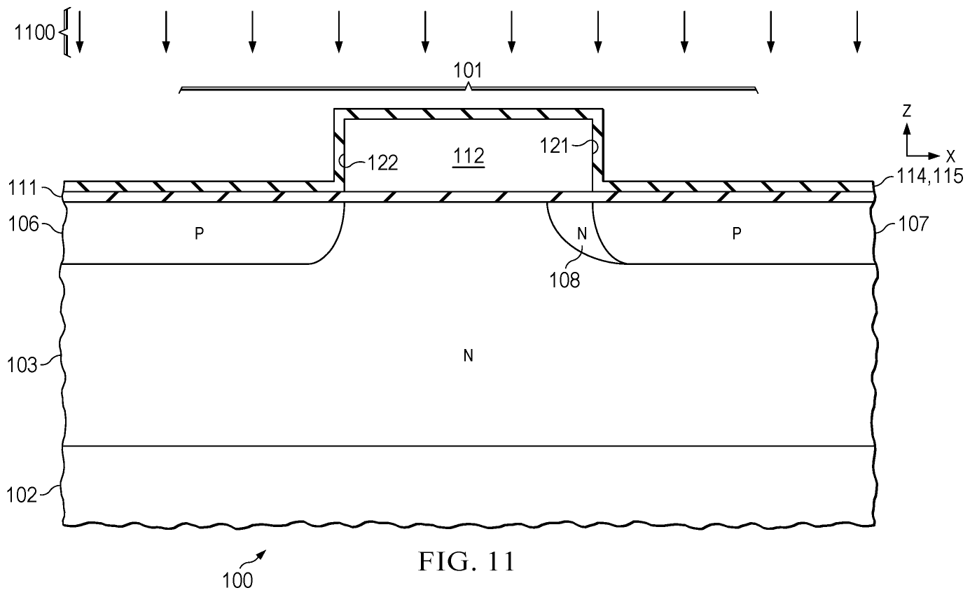

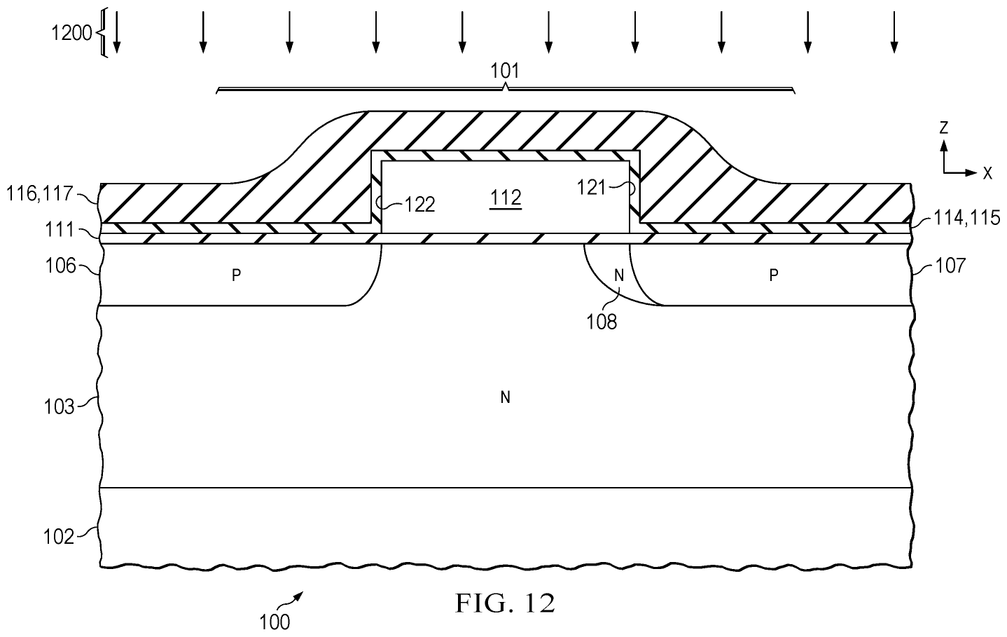

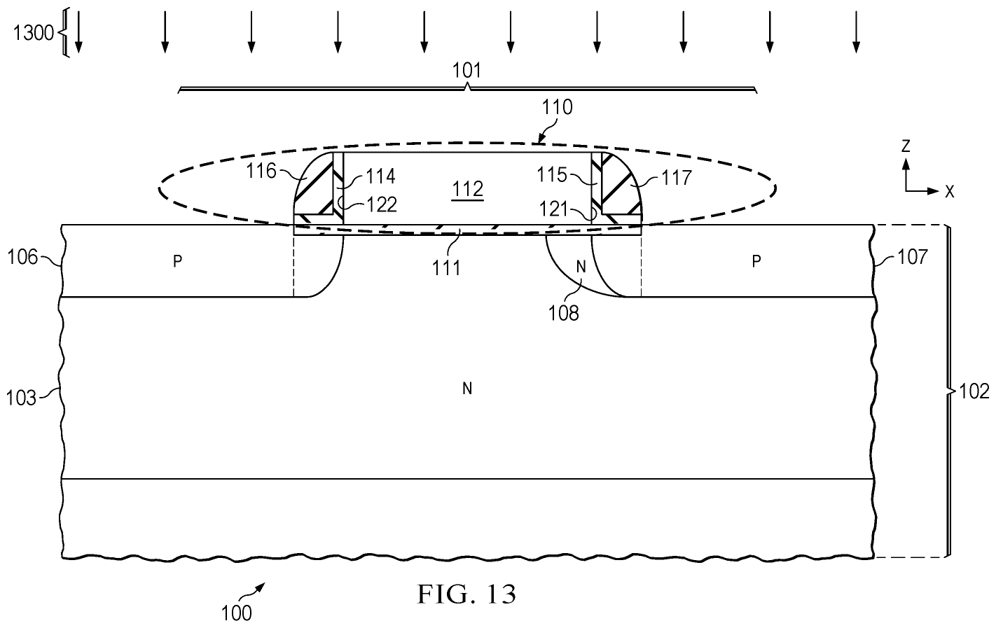

The method continues at 218, 220 and 222 in FIG. 2 with formation of the sidewall spacers along the lateral ends 121 and 122 of the patterned gate 112. At 218, an oxide layer is formed. FIG. 11 shows one example, in which a deposition process 1100 is performed that deposits silicon dioxide or other suitable material (labeled “114, 115”) over the exposed portions of the gate dielectric layer 111 and the patterned gate structure 112. At 220 in FIG. 2, a nitride layer is formed for the sidewall structures. FIG. 12 shows one example, in which a deposition process 1200 is performed that deposits silicon nitride, silicon oxynitride or other suitable material (labeled “116, 117” over the oxide layer 114, 115. The sidewall spacer layers are etched at 222 in FIG. 2. FIG. 13 shows one example, in which an etch process 1300 is performed that removes portions of the nitride layer 116, 117 and the oxide layer 114, 115 to expose the top side of the patterned gate structure 112 and laterally outward portions of the gate dielectric layer 111, and leaves the finished sidewall structures (layers 114, 116 and layers 115, 117) along the respective lateral ends 122 and 121 of the gate structure 112.

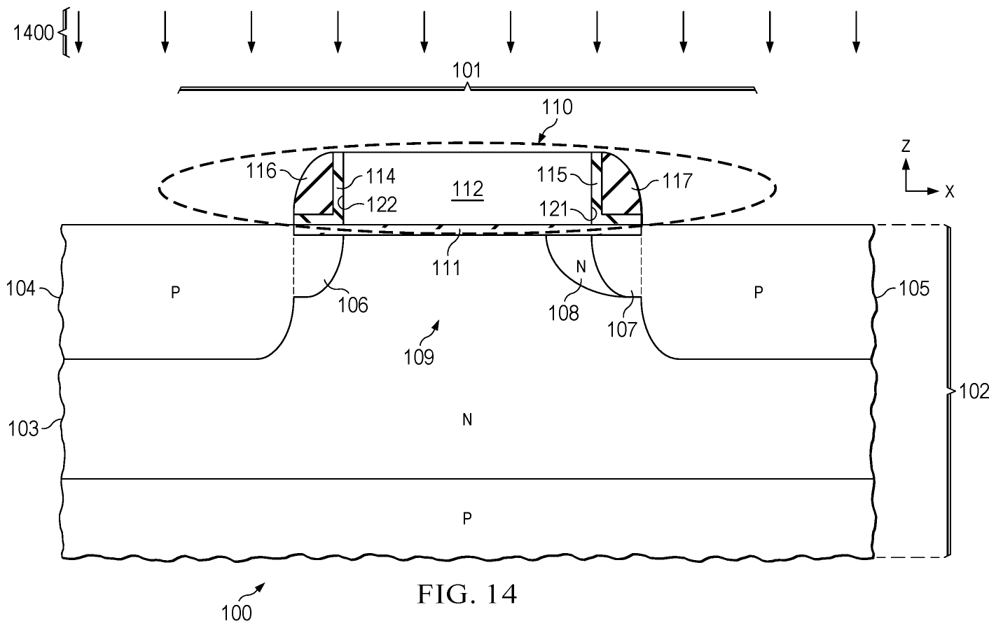

The method 200 continues at 224 in FIG. 2 with p-type source/drain implants. The implant process may be conventional, e.g., as performed for an analogous transistor lacking the enhanced channel region 108. FIG. 14 shows one example, in which an implantation process 1400 is performed that implants boron or other p-type dopants to form the respective first and second source/drain regions 104 and 105, where the implantation process 1400 in certain implementations can supplement the concentration of p-type charge carriers in the exposed portions of the PLDD implanted regions 106 and 107. In one example, the implantation process 1400 implants the first source/drain region 104 with p-type charge carriers adjacent to the channel region 109 proximate the second end 122 of the gate 112 and spaced apart from the enhanced channel region 108 in the n-well 103. In this example, moreover, the implantation process 1400 implants the second source/drain region 105 with p-type charge carriers adjacent to the enhanced channel region 108 in the n-well 103. After the implantation process 1400 in one example, the enhanced channel region 108 is adjacent the second source/drain region 105 at the surface of the n-well 103 and under the first end 121 of the floating gate 112, the channel region 109 is adjacent the first source/drain region 104 under the second end 122 of the floating gate 112 at the surface of the n-well 103, the channel region 109 has a first majority charge carrier concentration of n-type majority charge carriers, and the enhanced channel region 108 has a second majority charge carrier concentration of n-type majority charge carriers that is greater than the first majority charge carrier concentration.

Modifications are possible in the described examples, and other implementations are possible, within the scope of the claims.

What is claimed is:

1. An electronic device, comprising a non-volatile memory cell including:
a channel region having a first conductivity type between first and second source/drain regions having an opposite second conductivity type over a semiconductor substrate, the channel region touching the first source/drain region;
a gate structure over the channel region, the gate structure including a gate dielectric layer over the channel region and a floating gate over the gate dielectric layer; and
an enhanced channel region having the first conductivity type touching the second source/drain region and the channel region at a surface of the substrate.

2. The electronic device of claim 1, wherein: the enhanced channel region extends from under a first end of the floating gate toward an opposite second end of the floating gate at the surface of the substrate.

3. The electronic device of claim 1, wherein: the channel region has a first majority charge carrier concentration of the majority charge carriers of the second conductivity type; and the enhanced channel region has a second majority charge carrier concentration of the majority charge carriers of the second conductivity type that is greater than the first majority charge carrier concentration.

4. The electronic device of claim 1, comprising a read circuit configured to identify a program state of the non-volatile memory cell as one of a first state, a second state, and a third state based on a cell voltage of the non-volatile memory cell, the first, second, and third states being different from one another.

5. The electronic device of claim 4, wherein the read circuit comprises:
a comparator circuit configured to compare the cell voltage to first and second threshold voltages, an absolute value of the second threshold voltage greater than an absolute value of the first threshold voltage; and
a logic circuit configured to:
identify the program state as the first state responsive to the cell voltage being less than the first and second threshold voltages;
identify the program state as the second state responsive to the cell voltage being greater than or equal to the first threshold voltage and less than the second threshold voltage; and
identify the program state as the third state responsive to the cell voltage being greater than the first threshold voltage and greater than or equal to the second threshold voltage.

6. The electronic device of claim 4, comprising a write circuit configured to selectively set the program state of the non-volatile memory cell to one of the first, second, and third states.

7. The electronic device of claim 1, comprising a write circuit configured to selectively set a program state of the non-volatile memory cell to one of a first state, a second state, and a third state, the first, second, and third states being different from one another.

8. The electronic device of claim 7, wherein the write circuit comprises:
a voltage source having an output configured to provide a programming voltage signal; and
a switching circuit configured to:
prevent connection of the output of the voltage source to the non-volatile memory cell to retain the program state of the non-volatile memory cell in the first state;
connect the output of the voltage source to the second source/drain region to set the program state of the non-volatile memory cell to the second state; and
connect the output of the voltage source to the first source/drain region to set the program state of the non-volatile memory cell to the third state.

9. The electronic device of claim 1, wherein the first conductivity type is p-type and the second conductivity type is n-type.

10. The electronic device of claim 1, wherein the non-volatile memory cell is selectively programmable to change a program state of the non-volatile memory cell from a first state to: a second state; or a third state.

11. The electronic device of claim 10, wherein:
the floating gate has a first amount of accumulated charge in the floating gate in the first state;
the non-volatile memory cell is selectively programmable to accumulate charge in the floating gate to change the program state from the first state to the second state having a second amount of accumulated charge in the floating gate, the second amount of accumulated charge being greater than the first amount of accumulated charge; and
the non-volatile memory cell is selectively programmable to accumulate charge in the floating gate to change the program state from the first state to the third state having a third amount of accumulated charge in the floating gate, the third amount of accumulated charge being greater than the second amount of accumulated charge.

12. The electronic device of claim 10, wherein:
the non-volatile memory cell is selectively programmable to change the program state from the first state to the second state by applying a programming voltage signal to the second source/drain region; and
the non-volatile memory cell is selectively programmable to change the program state from the first state to the third state by applying the programming voltage signal to the first source/drain region.

13. A non-volatile memory, comprising:
a non-volatile memory cell with an asymmetric floating gate cell transistor selectively programmable to change a program state from a first state to a second state or a third state, the non-volatile memory cell comprising an asymmetrical channel region between a first source/drain region and a second source/drain region in a substrate under a floating gate, the asymmetrical channel region having an enhanced channel region adjacent the first source/drain region at a surface of the substrate; and
a read circuit configured to identify the program state of the non-volatile memory cell as one of the first state, the second state, and the third state based on a cell voltage of the non-volatile memory cell.

14. The non-volatile memory of claim 13, comprising a write circuit configured to selectively change the program state from the first state to the second state by applying a programming voltage signal to the first source/drain region and to selectively change the program state from the first state to the third state by applying the programming voltage signal to the second source/drain region.

15. The non-volatile memory of claim 14, wherein: the first source/drain region and the second source/drain region include majority charge carriers of a first conductivity type; and the asymmetrical channel region and the enhanced channel region include majority charge carriers of an opposite second conductivity type.

16. The non-volatile memory of claim 14, wherein:
the floating gate has a first amount of accumulated charge in the first state;
the non-volatile memory cell is selectively programmable to accumulate charge in the floating gate to change the program state from the first state to the second state having a second amount of accumulated charge in the floating gate, the second amount of accumulated charge being greater than the first amount of accumulated charge; and
the non-volatile memory cell is selectively programmable to accumulate charge in the floating gate to change the program state from the first state to the third state having a third amount of accumulated charge in the floating gate, the third amount of accumulated charge being greater than the second amount of accumulated charge.

17. The non-volatile memory of claim 16, wherein:
the non-volatile memory cell is selectively programmable to change the program state from the first state to the second state by applying a programming voltage signal to the first source/drain region; and
the non-volatile memory cell is selectively programmable to change the program state from the first state to the third state by applying the programming voltage signal to the second source/drain region.

18. A method of fabricating an electronic device, the method comprising:
forming a gate dielectric layer over a surface of a channel region of a semiconductor substrate, the channel region including majority charge carriers of a second conductivity type;
forming a gate structure with opposite first and second sidewalls over the gate dielectric layer;
implanting dopants of the second conductivity type under the first sidewall of the floating gate while blocking the dopants from the second sidewall of the floating gate; and
implanting dopants of an opposite first conductivity type into the substrate adjacent the first and second sidewalls of the gate structure, thereby forming first and second source/drain regions.

19. The method of claim 18, wherein implanting the dopants of the second conductivity type includes implanting a dopant species with a flux in a range from 2.07×10¹³ atoms·cm⁻² to 2.53×10¹³ atoms·cm⁻².

20. The method of claim 18, wherein implanting the dopants of the second conductivity type produces an enhanced channel region with a first concentration of majority carriers of the second conductivity type extending from the first sidewall toward the second sidewall, and a channel region that extends from the enhanced channel region toward the second sidewall has a lower concentration of majority carriers of the second conductivity type.
